(19) United States
(12) Patent Application Publication
(10) Pub. No.: US 2008/0011452 A1
(43) Pub. Date: Jan. 17, 2008

(54) HEAT SINK

(75) Inventors: Hsiu-Chang Lai, Tu-Cheng (TW); Hung-Yi Wu, Tu-Cheng (TW); Zhen-Xing Ye, Shenzhen (CN); Ke Sun, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,588

(22) Filed: Aug. 26, 2006

(30) Foreign Application Priority Data
Jul. 14, 2006 (CN) 200610061647.0

(51) Int. Cl. H05K 7/20

(52) U.S. Cl. 165/80.3; 361/704

(57) ABSTRACT

A heat sink includes a base, and a plurality of parallel fins extending up from the base. Every two adjacent fins are spaced from each other with a passage formed therebetween. The passage has an air inlet at one side of the heat sink and an air outlet at an opposite side of the heat sink. A height of each fin gradually reduces from a middle portion to opposite sides of the fin near the inlet and outlet of the passage respectively.

### FIELD OF THE INVENTION

The present invention relates to heat sinks, and more particularly to a heat sink having high heat dissipation efficiency.

### DESCRIPTION OF RELATED ART

Advances in microelectronics technology have caused electronic devices, which process signals and data, at unprecedented high speeds when working. During operation of many contemporary electronic devices, such as CPUs (Central Processing Units), large amounts of heat are produced. The heat must be efficiently removed, to prevent the system from becoming unstable or being damaged. Heat sinks are frequently used to dissipate heat from these electronic devices.

Referring to FIG. 3 and FIG. 4, a conventional heat sink 10 includes a base 12, and a plurality of parallel fins 14 extending up from the base 12. The base 12 is a tablet shaped metal block with flat top and bottom surfaces. The heat sink 10 is configured for being attached to an electronic device (not shown), such as a CPU, for heat dissipation. That is, the bottom surface of the base 12 clings to the electronic device.

A fan (not shown) is set, to assist in heat dissipation, at a certain distance from the heat sink 10. Airflow from the fan enters the heat sink 10 through an air inlet 13 of the heat sink 10, and exits from an air outlet 15 of the heat sink 10. The airflow includes a first airflow 110 passing through an upside of the fins 14, a second airflow 112 passing through a middle of the fins 14, and a third airflow 114 passing through a bottom of the fins 14. Because sides of each fin 14 nearby the air inlet 13 is approximately vertical to the airflow, thus, resistance of the airflow is much greater when passing through the heat sink 10, thereby reducing heat dissipation of the heat sink 10.

What is desired, therefore, is a heat sink which provides high efficiency of heat dissipation.

### SUMMARY OF THE INVENTION

In one preferred embodiment, a heat sink includes a base, and a plurality of parallel fins extending up from the base. Every two adjacent fins are spaced from each other with a passage formed therebetween. The passage has an air inlet at one side of the heat sink and an air outlet at an opposite side of the heat sink. A height of each fin gradually reduces from a middle portion to opposite sides of the fin near the inlet and outlet of the passage respectively.

Other advantages and novel features will become more apparent from the following detailed description of preferred embodiments when taken in conjunction with the accompanying drawings, in which:

### BRIEF DESCRIPTION OF THE DRAWINGS

FIG. 1 is an isometric view of a heat sink, in accordance with a preferred embodiment of the present invention;

FIG. 2 is a front views of FIG. 1;

FIG. 3 is an isometric view of a conventional heat sink; and

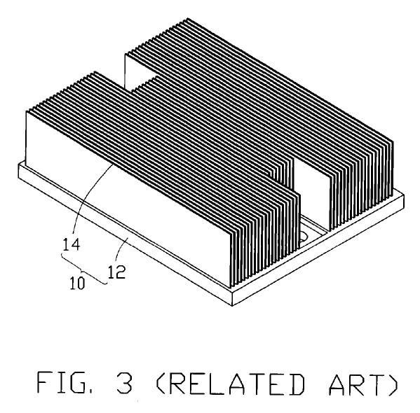

FIG. 4 is a front view of FIG. 3.

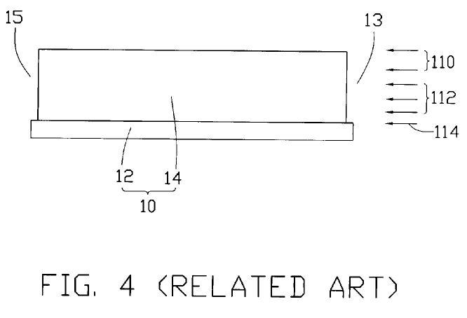

### DETAILED DESCRIPTION OF THE INVENTION

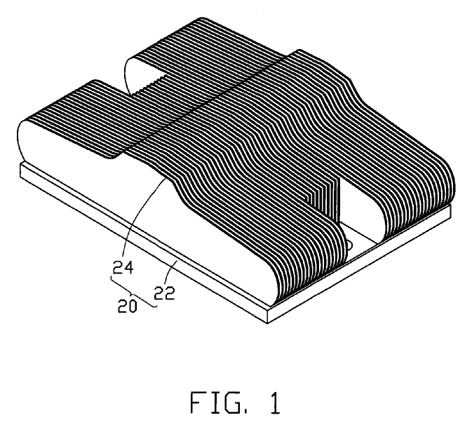

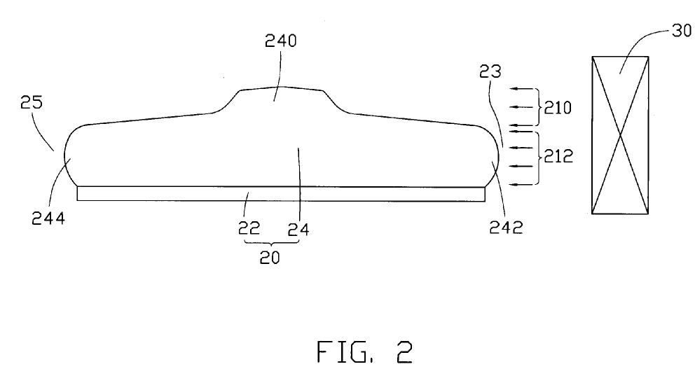

As shown in FIG. 1 and FIG. 2, in a preferred embodiment of the present invention, a heat sink 20 includes a heat-conductive base 22, and a plurality of parallel fins 24 extending up from the base 22. Every two adjacent fins 24 are spaced from each other with a passage formed therebetween. The passage has an air inlet 23 at one side of the heat sink 20 and an air outlet 25 at an opposite side of the heat sink 20. A height of each fin 24 gradually reduces from a middle portion 240 to opposite sides 242, 244 of the fins 24 near the air inlet 23 and the air outlet 25 of the passage respectively.

An airflow generating device, such as a fan 30 is set, to assist in heat dissipation, at a certain distance from the heat sink 20. Airflow from the fan 30 enters through the air inlet 23 of the heat sink 20, and exits from the air outlet 25 of the heat sink 20. In the preferred embodiment, each of the fins 24 is generally in a shape of a submarine with the raised portion 240 in a middle thereof. The raised portion 240 of each fin 24 is highest, and the height of each fin 24 gradually reduces from both opposite sides of the raised portion 240 to the corresponding sides 242, 244 of the fins 24 near the air inlet 23 and the air outlet 25 of the passage respectively. The sides 242, 244 of each fin 24 near the air inlet 23 and the air outlet 25 are generally in a shape of a smooth camber respectively. Each fin 24 also may be arc shaped and higher in a middle thereof.

In use, the heat sink 20 is attached to an electronic device, such as a CPU, for heat dissipation. A top surface of the electronic device is located under, and attached to, a bottom surface of the base 22.

The airflow includes a first airflow 210 passing through passages between tops of every two adjacent fins 24 of the heat sink 20, and a second airflow 212 passing through passages between remaining parts of the every two adjacent fins 24. Because of the general streamlined shape of each of the fins 24, resistance of the airflow is minimized. Therefore, this aerodynamic design allows better airflow through the heat sink 20.

It is to be understood, however, that even though numerous characteristics and advantages of the preferred embodiments have been set forth in the foregoing description, together with details of the structures and functions of the embodiments, the disclosure is illustrative only, and changes may be made in detail, especially in matters of shape, size, equivalent material and arrangement of parts within the principles of the invention to the full extent indicated by the broad general meaning of the terms in which the appended claims are expressed.

What is claimed is:

1. A heat sink comprising:
a heat-conductive base including a top surface and a bottom surface; and
a plurality of parallel fins extending up from the top surface of the base, every two adjacent fins being spaced from each other with a passage formed therebetween, and the passage having an air inlet at one side of the heat sink, and an air outlet at an opposite side of the heat sink, a height of each fin gradually reducing from a middle portion to opposite sides near the inlet and outlet of the passage respectively.

2. The heat sink as claimed in claim 1, wherein each of the fins has a raised portion in the middle thereof, the height of each of the fins gradually reduces from both opposite sides of the raised portion to the corresponding sides of the fins near the air inlet and the air outlet of the passage respectively.

3. The heat sink as claimed in claim 1, wherein each of the fins is arc shaped and higher in a middle thereof.

4. The heat sink as claimed in claim 2, wherein a side of each of the fins near the air inlet is generally in a shape of a smooth camber.

5. The heat sink as claimed in claim 2, wherein a side of each of the fins near the air outlet is generally in a shape of a smooth camber.

6. The heat sink as claimed in claim 2, wherein the raised portion has an arcuate top side.

7. A heat sink assembly comprising:
a heat-conductive base;
a plurality of parallel fins extending from the base, a passage being defined between every adjacent two fins for airflow flowing therethrough, the passage having an inlet located at one side of the fins and an outlet at an opposite side of the fins, one side of each of the fins near the inlet having a smooth camber; and
an airflow generating device configured for producing airflow to enter the passage via inlet and exist the passage via the outlet.

8. The heat sink as claimed in claim 7, wherein each of the fins has a raised portion in the middle thereof, the height of each of the fins gradually reduces from both opposite sides of the raised portion to the corresponding sides of the fins near the air inlet and the air outlet of the passage respectively.

9. The heat sink as claimed in claim 7, wherein each of the fins is arc shaped and higher in a middle thereof.

10. The heat sink as claimed in claim 8, wherein a side of each of the fins near the air outlet is generally in a shape of a smooth camber.

11. The heat sink as claimed in claim 8, wherein the raised portion has an arcuate top side.
